(19) United States
(12) Patent Application Publication
(10) Pub. No.: US 2014/0123898 A1
(43) Pub. Date: May 8, 2014

(54) CHARGED PARTICLE BEAM DEVICE

(71) Applicants: Tsunenori Nomaguchi, Tokyo (JP); Toshihide Agemura, Tokyo (JP)

(72) Inventors: Tsunenori Nomaguchi, Tokyo (JP); Toshihide Agemura, Tokyo (JP)

(73) Assignee: HITACHI HIGH-TECHNOLOGIES CORPORATION, Tokyo (JP)

(21) Appl. No.: 14/129,209

(22) PCT Filed: Jun. 6, 2012
(86) PCT No.: PCT/JP2012/064500

§ 371 Date: Dec. 24, 2013

(30) Foreign Application Priority Data
Jul. 14, 2011 (JP) 2011-155945

(51) Int. Cl. H01J 37/26; H01J 37/317

(52) U.S. Cl. CPC H01J 37/26; H01J 37/317
USPC 118/723 FI; 250/306; 118/713

(57) ABSTRACT

A charged particle beam device includes: a sample stage (146) supporting a sample; a charged particle beam optical system that focuses a charged particle beam from a charged particle source on the sample; a charged particle beam column (101) housing the charged particle beam optical system; a first differential evacuation diaphragm (108) attached to the charged particle beam column (101); a frontal sample chamber (103) disposed in connection with the charged particle beam column (101) via the first differential evacuation diaphragm (108); a second differential evacuation diaphragm (109) attached to the frontal sample chamber (103); a first vacuum pump (141) for evacuating the charged particle beam column (101); and a second vacuum pump (142) for evacuating the frontal sample chamber (103).

### TECHNICAL FIELD

The present invention relates to a charged particle beam device for processing or observing a sample by using a charged particle beam.

### BACKGROUND ART

In recent years, there has been a need for observing hydrous materials or moist substances, such as a biological sample, by using a transmission electron microscope (TEM) or a scanning transmission electron microscope (STEM). For TEM or STEM observation, a thin-film sample with the thickness on the order of tens to hundreds of nanometers needs to be prepared. As a method of preparing such a thin-film sample for TEM or STEM observation, a processing method using a charged particle beam is known. For example, a method of preparing a thin-film sample for TEM or STEM observation from a semiconductor wafer by using a focused ion beam (FIB) is known.

### PRIOR ART DOCUMENTS

### Patent Documents

Patent Document 1: JP Patent (Kokai) Publication No. 2006-260878 A

Patent Document 2: JP Patent (Kokai) Publication No. 2006-32011 A

### SUMMARY OF THE INVENTION

### Problem to be Solved by the Invention

The present inventors conducted vigorous analysis of technology for preparing a thin-film sample for TEM or STEM observation from hydrous materials or moist substances, such as a biological sample, by using a focused ion beam (FIB), and gained the following insights.

In a focused ion beam (FIB) device, a sample as an object for processing and observation is held in an evacuated sample chamber. When the sample held in the evacuated sample chamber contains water or gas, problems such as denaturation of the sample due to drying, or rupture of the sample due to gas emission may be caused.

In order to suppress the drying of the sample, a method may freeze the sample. However, in this case, a cooling mechanism needs to be installed. Further, the freezing causes water expansion, whereby the object for observation could possibly be deformed or destroyed.

Thus, a method by which the sample is supported under low vacuum may be considered. Patent Documents 1 and 2 disclose examples of the scanning electron microscope (SEM) in which a sample supported in a low vacuum area is observed by using a differential evacuation mechanism.

In the focused ion beam (FIB) device, equipment such as a gas deposition unit, a micro-sampling unit, and the like need to be installed near the sample. Thus, in the focused ion beam (FIB) device, the structure around the sample needs to be simplified, compared with the scanning electron microscope (SEM).

An object of the present invention is to provide a charged particle beam device such that low vacuum can be maintained around a sample and the structure around the sample can be simplified.

### Means for Solving the Problem

A charged particle beam device according to the present invention includes a sample stage supporting a sample; a charged particle beam optical system that focuses a charged particle beam from a charged particle source on the sample; a charged particle beam column housing the charged particle beam optical system; a first differential evacuation diaphragm attached to the charged particle beam column; a frontal sample chamber disposed in connection with the charged particle beam column via the first differential evacuation diaphragm; a second differential evacuation diaphragm attached to the frontal sample chamber; a first vacuum pump for evacuating the charged particle beam column; and a second vacuum pump for evacuating the frontal sample chamber.

The charged particle beam from the charged particle source is configured to irradiate the sample via the charged particle beam optical system, the first differential evacuation diaphragm, and the second differential evacuation diaphragm; the first vacuum pump and the second vacuum pump are controlled such that P1<P2<P3, where P1 is an air pressure of the charged particle beam column, P2 is an air pressure of the frontal sample chamber, and P3 is an air pressure of a space around the sample; and the first and second differential evacuation diaphragms have an internal diameter of not more than 2 mm.

### Effects of the Invention

According to the present invention, a charged particle beam device such that low vacuum can be maintained around a sample and the structure around the sample can be simplified can be provided.

### BRIEF DESCRIPTION OF THE DRAWINGS

FIG. 1 is a diagram of the configuration of a first example of a charged particle beam device according to the present invention.

FIG. 2 is a diagram of the configuration of a second example of the charged particle beam device according to the present invention.

FIG. 3 is a diagram of the configuration of a third example of the charged particle beam device according to the present invention.

FIG. 4 is a diagram of the configuration of a fourth example of the charged particle beam device according to the present embodiment.

FIG. 5 is a diagram of the configuration of a fifth example of the charged particle beam device according to the present invention.

FIG. 6 is a diagram of the configuration of a sixth example of the charged particle beam device according to the present invention.

FIG. 7 is a diagram of the configuration of a seventh example of the charged particle beam device according to the present invention.

### MODE FOR CARRYING OUT THE INVENTION

An embodiment of the present invention will be described with reference to the drawings. The present embodiment is merely an example of implementation of the present invention, and does not limit the technical scope of the present invention. Throughout the drawing figures, common configurations are designated with similar reference numbers.

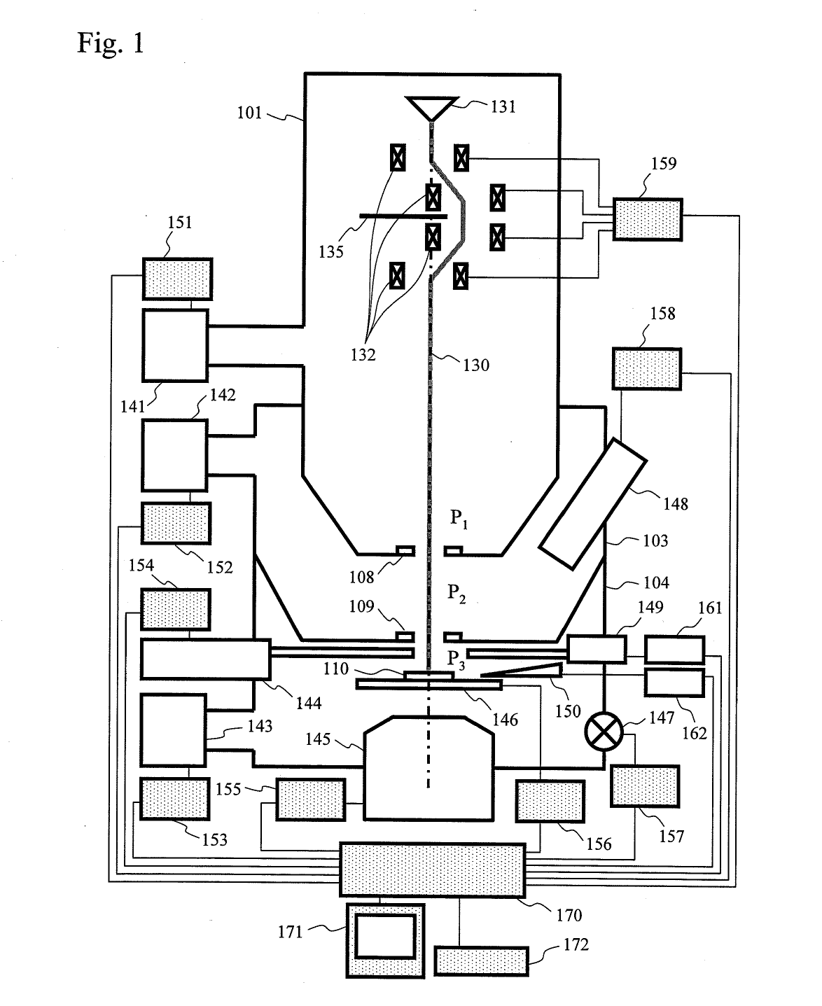

With reference to FIG. 1, a first example of the charged particle beam device according to the present invention will be described. The charged particle beam device in the present example includes a charged particle beam column 101, a frontal sample chamber 103 disposed under the charged particle beam column 101, and a sample chamber 104 disposed under the frontal sample chamber 103, which are airtight containers. At the lower end of the charged particle beam column 101, a first differential evacuation diaphragm 108 is disposed. At the lower end of the frontal sample chamber 103, a second differential evacuation diaphragm 109 is disposed. The charged particle beam column 101 and the frontal sample chamber 103 are connected via the first differential evacuation diaphragm 108. The frontal sample chamber 103 and the sample chamber 104 are connected via the second differential evacuation diaphragm 109. The differential evacuation diaphragms 108 and 109 may include ring-shaped members with an internal diameter of not more than 2 mm. The charged particle beam column 101, the frontal sample chamber 103, and the sample chamber 104 are mutually connected via the differential evacuation diaphragms 108 and 109; otherwise, they have airtight container structures.

In the charged particle beam column 101, a charged particle beam optical system is housed. The charged particle beam optical system according to the present example includes a charged particle source 131 for generating a charged particle beam 130, a group of deflectors 132 for bending the charged particle beam 130, and a shielding plate 135 disposed in such a manner as to intersect the optical axis of the charged particle beam 130. The group of deflectors 132 is controlled by a deflector group controller 159. The function of the shielding plate 135 will be described below.

The frontal sample chamber 103 is provided with a detector 148 for detecting a signal generated by irradiating a sample 110 with the charged particle beam. The detector 148 is controlled by a detector controller 158.

The sample chamber 104 is provided with a sample stage 146 for supporting the sample 110, moving the sample 110 in a plane or rotationally, or inclining the sample 110. The sample chamber 104 is also provided with an optical microscope 145 located under the sample stage 146. The sample stage 146 is controlled by a sample stage controller 156. The optical microscope 145 is controlled by an optical microscope controller 155. The function of the optical microscope 145 will be described below.

In the present example, the first and second differential evacuation diaphragms 108 and 109, the sample stage 146, and the optical microscope 145 are disposed along the optical axis of the charged particle source 131.

The charged particle beam column 101 is provided with a first vacuum pump 141. The frontal sample chamber 103 is provided with a second vacuum pump 142. The sample chamber 104 is provided with a third vacuum pump 143, a helium gas introduction unit 144, and a valve 147. The sample chamber 104 is further provided with a gas deposition unit 149 and a micro-sampling unit 150.

The first, second, and third vacuum pumps 141, 142, and 143 are controlled by first, second, and third vacuum pump controllers 151, 152, and 153, respectively. The helium gas introduction unit 144 and the valve 147 are controlled by a helium gas introduction unit controller 154 and a valve controller 157, respectively. The gas deposition unit 149 and the micro-sampling unit 150 are controlled by a gas deposition unit controller 161 and a micro-sampling unit controller 162, respectively. The function of the helium gas introduction unit 144 will be described below.

The controllers 151, 152, 153, 154, 155, 156, 157, 158, 159, 161, and 162 are connected to an integrated computer 170. The integrated computer 170 controls the operation of the device as a whole. The integrated computer 170 may be integrally controlled by one or a plurality of computers. The integrated computer 170 is connected to a controller (such as a keyboard and mouse) 172 for an operator to input various instructions, such as an irradiation condition, an electrode voltage condition, and a position condition, and to a display 171 for displaying a GUI screen for the operator to operate the charged particle beam device.

In the charged particle beam device according to the present example, the detector 148 is disposed in the frontal sample chamber 103. However, the detector 148 may be disposed in the sample chamber 104 or the charged particle beam column 101. A configuration without the detector 148 is also possible. While a secondary electron detector is generally used as the detector 148, any detector may be used as long as the detector can detect the signal generated by irradiating the sample with the charged particle beam. For example, a detector that detects ions produced by ionization by electrons emitted from the sample, an X-ray detector, or an STEM detector may be used. The signal detected by the detector 148 is sent to the integrated computer 170 via the detector controller 158. An image signal from the optical microscope 145 is sent to the integrated computer 170 via the optical microscope controller 155. The signal sent to the integrated computer 170 may be displayed on the display 171 or another display.

The charged particle beam optical system housed in the charged particle beam column 101 includes, though not shown, a focusing lens for focusing the charged particle beam 130, an objective lens, and a deflecting system for scanning and shifting the charged particle beam 130. There is further provided a column controller for controlling these elements. Illustration of the focusing lens, the objective lens, and the deflecting system is also omitted in the illustrated examples described below.

The gas deposition unit 149, which is used for forming a protection film or for marking, forms a deposited film by irradiation of a charged particle beam (such as a focused ion beam (FIB)). The gas deposition unit 149 may be configured to store a deposition gas and supply the gas via a nozzle tip as needed.

The micro-sampling unit 150 picks up a specific location of the sample in combination with sample processing or cutting by FIB. The micro-sampling unit 150 includes a probe that is movable in the sample chamber and a probe drive unit for driving the probe. The probe is used for removing a minute sample strip formed in the sample, or for supplying a potential to the sample by contacting the probe onto the sample surface.

While in the present example one charged particle beam column 101 is provided, two or more identical or different charged particle beam columns may be provided. For example, one or a plurality of gallium ion beam columns, helium ion beam columns, or electron beam columns may be provided.

### <Function of Differential Evacuation Mechanism>

The differential evacuation mechanism in the charged particle beam device according to the present example will be described. The charged particle beam column 101, the frontal sample chamber 103, and the sample chamber 104 are provided with first, second, and third vacuum pumps 141, 142, and 143, respectively. The first vacuum pump 141 includes an ion pump, a high-vacuum oil-diffusion pump, or a turbo-molecular pump, for example. The inside of the charged particle beam column 101 is maintained at high vacuum on the order of 10⁻⁹ to 10⁻⁴ Pa. The second vacuum pump 142 and the third vacuum pump 143 include a turbo-molecular pump, a low vacuum oil-diffusion pump, or a rotary pump, for example. The inside of the frontal sample chamber 103 is maintained at intermediate vacuum on the order of 100 to 10⁻⁴ Pa. The sample chamber 104 is maintained at low vacuum on the order of 1 to 300 Pa. The degree of vacuum in the sample chamber 104 is also adjusted by opening or closing the valve 147.

The first, second, and third vacuum pumps 141, 142, and 143 are independently controlled by the first, second, and third vacuum pump controllers 151, 152, and 153, respectively. The sample chamber 104 is provided with the valve 147. The valve 147 is independently controlled by the valve controller 157. The charged particle beam column 101, the frontal sample chamber 103, and the sample chamber 104 may be each provided with a device for measuring the degree of vacuum, and the measured degree of vacuum may be transmitted to the integrated computer 170. Based on differences between the current degrees of vacuum of the charged particle beam column 101, the frontal sample chamber 103, and the sample chamber 104 and preset degrees of vacuum, the integrated computer 170 transmits instruction signals to the controllers 151, 152, 153, and 157. Thus, the insides of the charged particle beam column 101, the frontal sample chamber 103, and the sample chamber 104 are maintained at desired degrees of vacuum at all times.

The present example is configured such that P₁<P₂<P₃, where P1 is the air pressure of the charged particle beam column 101, P2 is the air pressure of the frontal sample chamber 103, and P3 is the air pressure of the sample chamber 104. This relationship is also valid in the illustrated examples described below.

The charged particle beam column 101 and the frontal sample chamber 103 are connected via the first differential evacuation diaphragm 108. However, the first differential evacuation diaphragm 108 has a sufficiently small internal diameter that the degree of vacuum of the charged particle beam column 101 can be maintained at a degree of vacuum higher than the degree of vacuum of the frontal sample chamber 103. The frontal sample chamber 103 and the sample chamber 104 are connected via the second differential evacuation diaphragm 109. However, the second differential evacuation diaphragm 109 has a sufficiently small internal diameter that the degree of vacuum of the frontal sample chamber 103 can be maintained at a degree of vacuum higher than the degree of vacuum of the sample chamber 104. The internal diameter of the differential evacuation diaphragms 108 and 109 is not more than 2 mm.

In the present example, the inside of the charged particle beam column 101 can be maintained at high vacuum while the sample chamber 104 can be maintained at low vacuum or atmospheric pressure. Thus, the atmosphere around the sample 110 supported on the sample stage 146 can be kept at low vacuum or atmospheric pressure.

Accordingly, a sample containing water, such as a biotic sample or a biological cell, and a moist substance such as solder can be subjected to FIB processing. Further, around the sample 110, a number of gas molecules derived from air and the like exist. Thus, the influence of gas, if any, emitted from within the sample 110 by the charged particle beam irradiation is small. As a result, a sample containing gas, such as a porous material used in gas absorbing material, or a foamable material containing air bubbles can be easily processed by FIB.

When the sample is supported under low vacuum or atmospheric pressure, an advantage that charging of the sample can be suppressed can be obtained. Thus, an insulating material that has been difficult to process by FIB due to charging, such as ceramic materials or rubber materials, can be easily processed. Further, when the number of gas molecules that exist around the sample is large, the amount of heat released from the sample by thermal conduction is also increased. As a result, FIB processing of a sample that can be thermally denatured, such as resin materials and polymer materials, is facilitated.

In the charged particle beam device according to the present example, various materials that have been difficult to process by FIB can be easily processed by FIB. Preparation of a thin-film sample for TEM or STEM observation by FIB processing can be applied to greater varieties of material. Thus, the present invention provides the effect of significantly increasing the analysis efficiency as well as widening the scope of structural analysis by TEM or STEM observation.

The present invention provides the effect that samples of various materials can be handled not just for FIB processing but also for forming a deposited film by ion beam or electron beam irradiation, or for scanning ion image (SIM) or SEM image observation.

Under low vacuum or atmospheric pressure, there is the problem that the charged particle beam is easily scattered and energy loss is easily caused, compared with under high vacuum. Thus, the distance that the charged particle beam travels under low vacuum or atmospheric pressure may desirably be minimized. Thus, the distance between the second differential evacuation diaphragm 109 and the sample 110 may desirably be not more than 2 mm. In this way, the scattering of the charged particle beam and energy loss can be suppressed. Further, this enables fine processing or high-speed processing by FIB, deposited film formation by FIB or an electron beam, and high-resolution observation, even under low vacuum or atmospheric pressure.

### <Function of Helium Gas Introduction Unit>

Next, the helium gas introduction unit 144 of the charged particle beam device according to the present example will be described. In the present example, a gas with low charged particle beam scattering power, such as helium gas, is introduced locally in the path of the charged particle beam 130 under low vacuum or atmospheric pressure. As illustrated, helium gas is introduced in the path of the charged particle beam 130 between the second differential evacuation diaphragm 109 and the sample 110 by using the helium gas introduction unit 144. As a result, the gas that exists in the path of the charged particle beam 130 is substituted by the helium gas. Because the path of the charged particle beam 130 is occupied by the helium gas with low scattering power, the scattering of the charged particle beam and energy loss can be suppressed.

In the present example, improved performance can be obtained in fine processing or high-speed processing by FIB, deposited film formation by FIB or electron beam, and charged particle beam observation. The introduction of helium gas may be implemented regardless of the distance between the second differential evacuation diaphragm 109 and the sample 110.

### <Function of Shielding Plate>

The group of deflectors 132 and the shielding plate 135 in the charged particle beam device according to the present example will be described. When the path of the charged particle beam from the charged particle source to an irradiating position on the sample is straight, gaseous molecules scattered from around the sample may possibly reach the charged particle source. If the gaseous molecules reach the charged particle source, the charged particle source may be contaminated, and the operating life of the charged particle source may be shortened as a result.

Thus, in the present example, the shielding plate 135 is disposed on the optical axis of the charged particle source 131. The shielding plate 135 is disposed in such a manner as to intersect the optical axis of the charged particle source 131. Further, the path of the charged particle beam 130 from the charged particle source 131 is bent by the group of deflectors 132 in such a manner as to bypass the shielding plate 135. Thus, the path of the charged particle beam 130 from the charged particle source 131 to the irradiating position on the sample 110 is bent and not straight. Accordingly, the gaseous molecules scattered from around the sample are prevented from reaching the charged particle source 131, so that the charged particle source is not contaminated by the gaseous molecules from around the sample. Thus, the operating life of the charged particle source can be increased.

The shielding plate 135 may be provided with a mechanism, not shown, for driving the shielding plate and a controller, not shown, for controlling the driving of the shielding plate. When the shielding plate 135 is disposed in such a manner as to intersect the optical axis of the charged particle source 131 as shown, contamination of the charged particle source 131 by gaseous molecules scattered from around the sample can be prevented. When not required, the shielding plate 135 may be drawn out. In this case, the path of the charged particle beam 130 from the charged particle source 131 to the irradiating position on the sample 110 is straight.

In the illustrated example, the group of deflectors 132 includes four sets of deflectors. However, the number and location of the deflectors are not particularly limited as long as the charged particle beam 130 from the charged particle source 131 can be bent in such a manner as to bypass the shielding plate 135. For example, three sets of deflectors may be used to implement a similar system.

### <Function of Optical Microscope>

The optical microscope 145 in the charged particle beam device according to the present example will be described. When the sample 110 is processed by using the charged particle beam 130, an operator performs an FIB processing operation while observing the processed position of the sample 110 and the irradiating position of the charged particle beam 130. Thus, it is necessary to acquire an image of the processed position of the sample 110 during FIB processing. Normally, a secondary electron image obtained by the detector 148 is used.

However, with the secondary electron image obtained by the detector 148, it is difficult to identify the position for processing or forming a deposited film in the case of a broad charged particle beam irradiation. Particularly, in FIB processing, there is no emission of backscattered electrons with high energy, so that it is difficult to acquire a charged particle image under low vacuum or atmosphere.

In the present example, the processed position and the irradiating position of the charged particle beam can be identified by the optical microscope 145. For example, the irradiating position of the charged particle beam can be identified by confirming a processing mark formed by the charged particle beam irradiation with the optical microscope 145. A mechanical or electric adjustment may be conducted in advance so that the irradiating position of the charged particle beam can be aligned with the observation position of the optical microscope 145. In this way, the processed position by the charged particle beam can be determined based on an image from the optical microscope 145. Further, the relationship between the irradiating position of the charged particle beam and the observation position of the optical microscope 145 may be recorded in advance. In this way, the processed position by the charged particle beam can be determined based on an image from the optical microscope 145.

In the present example, the optical microscope 145 is disposed along the optical axis of the charged particle source 131. However, the position of the optical microscope 145 and the position of the optical axis are discretionary as long as the irradiating position of the charged particle source 131 on the sample can be observed. For example, the optical axis of the optical microscope 145 may be disposed at an angle with respect to the optical axis of the charged particle source 131.

<Position of Sample with Respect to Charged Particle Beam Column>

In the charged particle beam device according to the present example as shown in FIG. 1, the first differential evacuation diaphragm 108 is mounted at the lower end of the charged particle beam column 101; the frontal sample chamber 103 is disposed under the charged particle beam column 101; and the second differential evacuation diaphragm 109 is mounted at the lower end of the frontal sample chamber 103, with the sample 110 disposed underneath. However, this order may be reversed; namely, the first differential evacuation diaphragm 108 may be mounted at the upper end of the charged particle beam column 101; the frontal sample chamber 103 may be disposed on top of the charged particle beam column 101; and the second differential evacuation diaphragm 109 may be mounted at the upper end of the frontal sample chamber 103 with the sample 110 disposed on top.

In this case, the sample 110 may be disposed over the second differential evacuation diaphragm 109, whereby the sample stage 146 can be omitted. Further, the helium gas introduction unit 144, the gas deposition unit 149, and the micro-sampling unit 150 may be disposed in the frontal sample chamber 103.

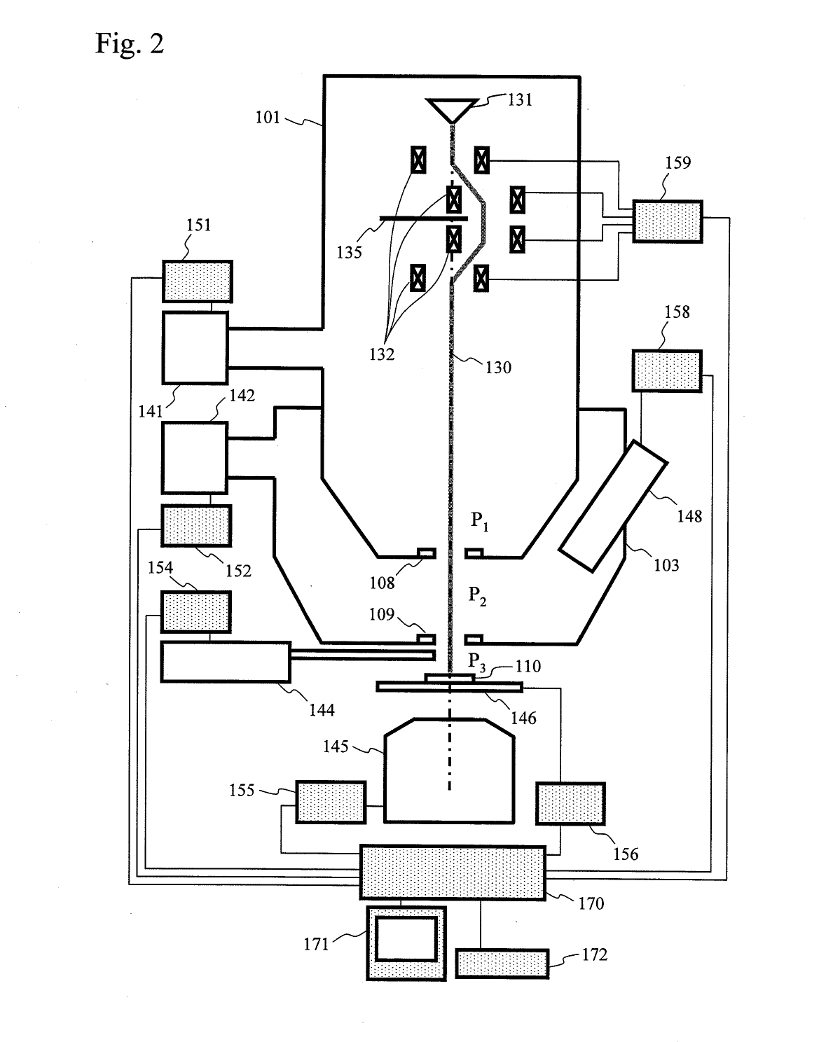

With reference to FIG. 2, a second example of the charged particle beam device according to the present invention will be described. In the charged particle beam device according to the present example, compared with the first example shown in FIG. 1, the sample chamber 104 is not provided. Thus, the third vacuum pump 143 with the third vacuum pump controller 153, and the valve 147 with the valve controller 157 that have been attached to the sample chamber 104 can be eliminated. Because the sample chamber 104 is not provided in the present example, the sample 110 supported on the sample stage 146 is in the atmosphere.

The present example is configured such that P1<P2<P3, where P1 is the air pressure of the charged particle beam column 101, P2 is the air pressure of the frontal sample chamber 103, and P3 is the air pressure of the space in which the sample 110 is disposed.

In the present example, processing or observation can be started immediately after the sample 110 is mounted on the sample stage 146. Namely, the time of evacuating the sample chamber 104 can be saved. Thus, the throughput of processing or observation, and convenience can be increased.

As described above, under atmospheric pressure compared with under high under vacuum, there is the problem that the charged particle beam is easily scattered and energy loss is easily produced. Thus, the distance that the charged particle beam travels under atmospheric pressure may desirably be minimized. Thus, the distance between the second differential evacuation diaphragm 109 and the sample 110 may preferably be not more than 2 mm. In this way, the scattering of the charged particle beam and energy loss can be suppressed. Further, even under atmospheric pressure, fine processing or high-speed processing by FIB, deposited film formation by FIB or an electron beam, or high-resolution observation can be performed.

In the present example, too, the order of arrangement of the charged particle beam column 101, the frontal sample chamber 103, and the sample 110 may be reversed from the order in the example of FIG. 1. Namely, the first differential evacuation diaphragm 108 may be mounted on the upper end of the charged particle beam column 101; the frontal sample chamber 103 may be disposed on top of the charged particle beam column 101; and the second differential evacuation diaphragm 109 may be mounted on the upper end of the frontal sample chamber 103 with the sample 110 disposed on top. In this case, the sample 110 may be disposed over the second differential evacuation diaphragm 109. In this way, the sample stage 146 can be omitted. Because the sample chamber is not provided in the present example, the sample can be replaced more easily.

In the present example and the examples below, a gas deposition unit, a micro-sampling unit, and the like are provided in the vicinity of the sample stage 146 but are not shown in the drawings.

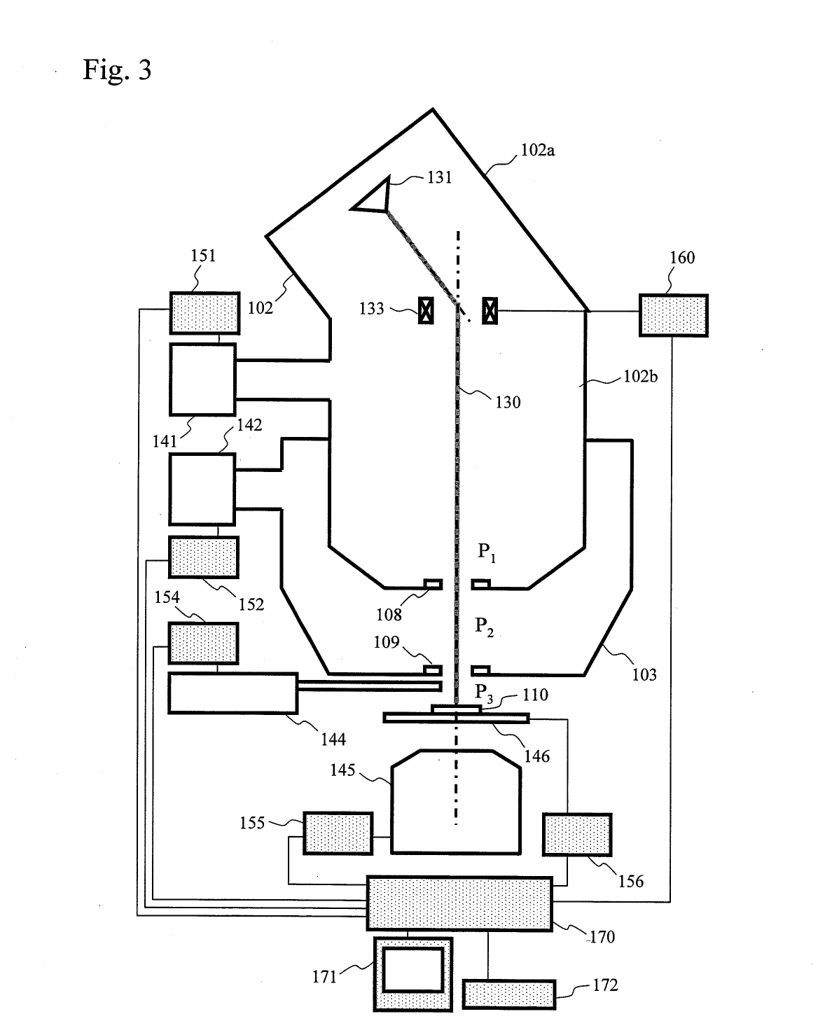

With reference to FIG. 3, a third example of the charged particle beam device according to the present invention will be described. Compared with the second example of FIG. 2, the charged particle beam device according to the present example is provided with a bent charged particle beam column 102. The charged particle beam column 102 includes a lower straight body portion 102b and an upper bent portion 102a. The charged particle source 131 is disposed in the bent portion 102a. The charged particle beam optical system according to the present example is provided with a deflector 133 for deflecting the charged particle beam 130, instead of the group of deflectors 132. The deflector 133 is controlled by a deflector controller 160. The charged particle beam optical system according to present example is not provided with the shielding plate 135.

The charged particle beam 130 from the charged particle source 131 is deflected by the deflector 133. Thus, the path of the charged particle beam 130 from the charged particle source 131 to the irradiating position on the sample 110 is deflected and not straight. Thus, the gaseous molecules scattered from around the sample cannot reach the charged particle source 131. Accordingly, the charged particle source is not contaminated by the gaseous molecules from around the sample, and the operating life of the charged particle source can be increased.

In the illustrated example, the detector 148 and the detector controller 158 are omitted. However, the detector 148 and the detector controller 158 may be provided in the present example. The detector 148 may be attached to the frontal sample chamber 103 or to the charged particle beam column 101.

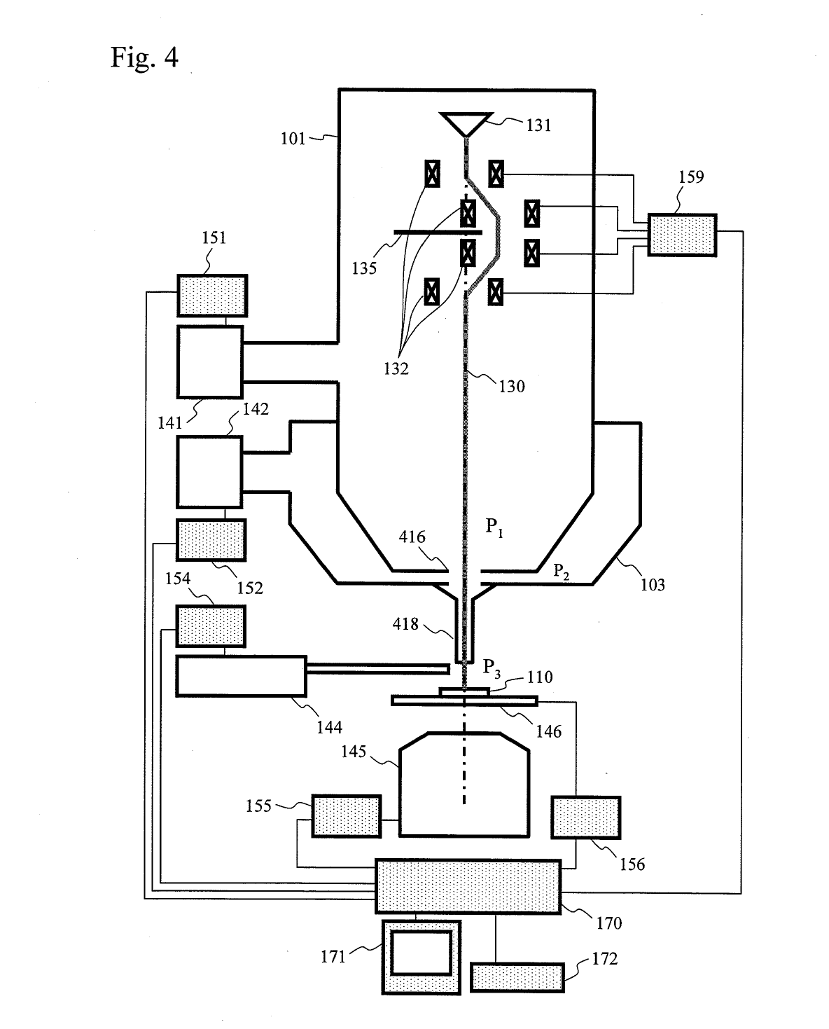

With reference to FIG. 4, a fourth example of the charged particle beam device according to the present invention will be described. In the charged particle beam device according to the present example, compared with the second example of FIG. 2, a differential evacuation pipe 418 is disposed at the lower end of the frontal sample chamber 103, instead of the second differential evacuation diaphragm 109. In the illustrated example, the first differential evacuation diaphragm 108 is not provided in an opening 416 at the lower end of the charged particle beam column 101.

The charged particle beam column 101 and the frontal sample chamber 103 are connected via the opening 416. The frontal sample chamber 103 and the space in which the sample 110 is disposed are connected via the differential evacuation pipe 418.

The present example is configured such that P1<P2<P3, where P1 is the air pressure of the charged particle beam column 101, P2 is the air pressure of the frontal sample chamber 103, and P3 is the air pressure of the space in which the sample 110 is disposed.

The differential evacuation pipe 418 may have a cylindrical shape, a tapered funnel shape, a conical shape, or a shape combining pipes of different diameters. The outer shape of the differential evacuation pipe 418 is not particularly limited as long as the differential evacuation pipe 418 includes a pipe somewhere inside. The differential evacuation pipe 418 may have an internal diameter of not more than 3 mm.

The length and internal diameter of the differential evacuation pipe 418 are set such that the flow volume of air that flows through the differential evacuation pipe 418 per unit time is set to be smaller than the flow volume of air that flows through the second differential evacuation diaphragm 109 per unit time. Thus, the pressure differences between the inside of the charged particle beam column 101, the inside of the frontal sample chamber 103, and the space in which the sample 110 is disposed can be easily increased. Accordingly, the scattering of the charged particle beam and energy loss can be further decreased.

In the present example, because the differential evacuation pipe 418 is used, devices or structures, such as the helium gas introduction unit, the gas deposition unit, and the micro-sampling unit, can be disposed near the sample 110. Further, because the differential evacuation pipe 418 is a long and thin tubular member in the present example, the exit of the differential evacuation pipe 418 can be located close to the surface of the sample 110 even when the space around the sample 110 is occupied by various devices or structures. Thus, the distance that the charged particle beam travels under atmospheric pressure can be made sufficiently short, whereby the scattering of the charged particle beam and energy loss can be avoided.

In the present example, as in the second example of FIG. 2, the sample chamber 104 is omitted. However, the sample chamber 104 may be provided, as in the first example of FIG. 1. While in the present example the detector 148 is omitted, the detector 148 may be provided. The detector 148 may be attached to the frontal sample chamber 103, the sample chamber 104, or the charged particle beam column 101.

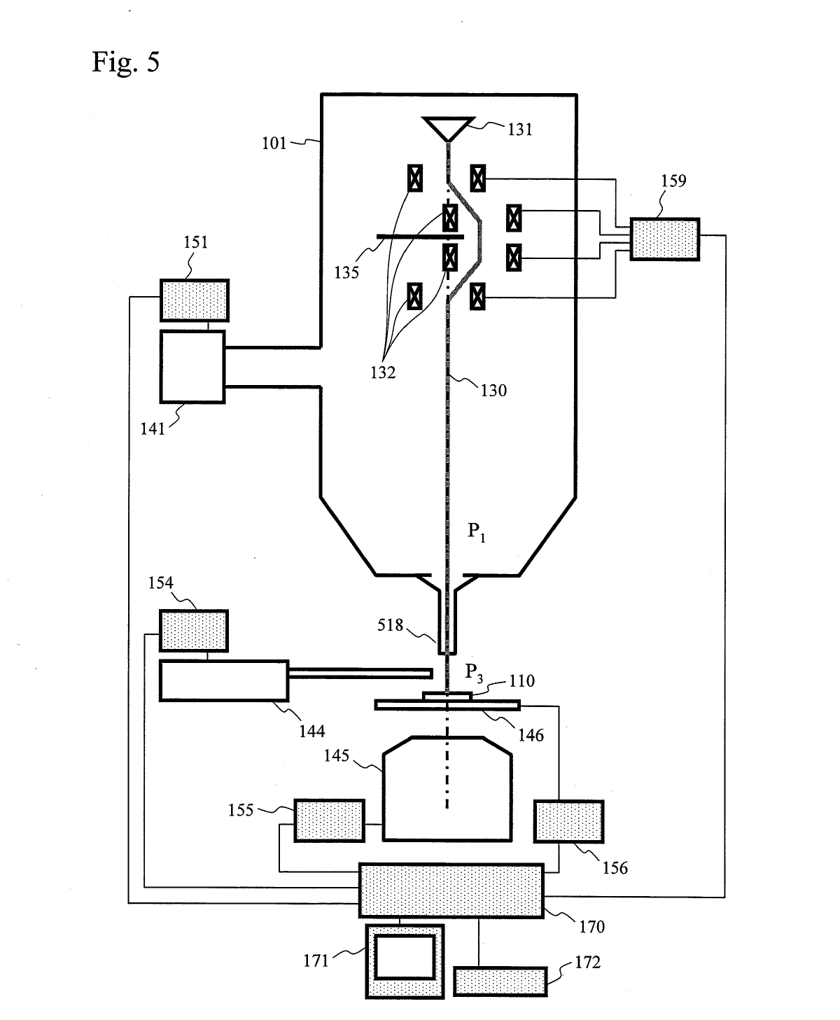

With reference to FIG. 5, a fifth example of the charged particle beam device according to the present invention will be described. The charged particle beam device according to the present example differs from the fourth example of FIG. 4 in that the frontal sample chamber 103 is omitted, and that the charged particle beam column 101 is provided with a differential evacuation pipe 518. In the present example, the charged particle beam column 101 and the space in which the sample 110 is disposed are connected via the differential evacuation pipe 518. In the present example, the second vacuum pump 142 and the second vacuum pump controller 152 that have been attached to the frontal sample chamber 103 are not required, whereby the device configuration can be more simplified.

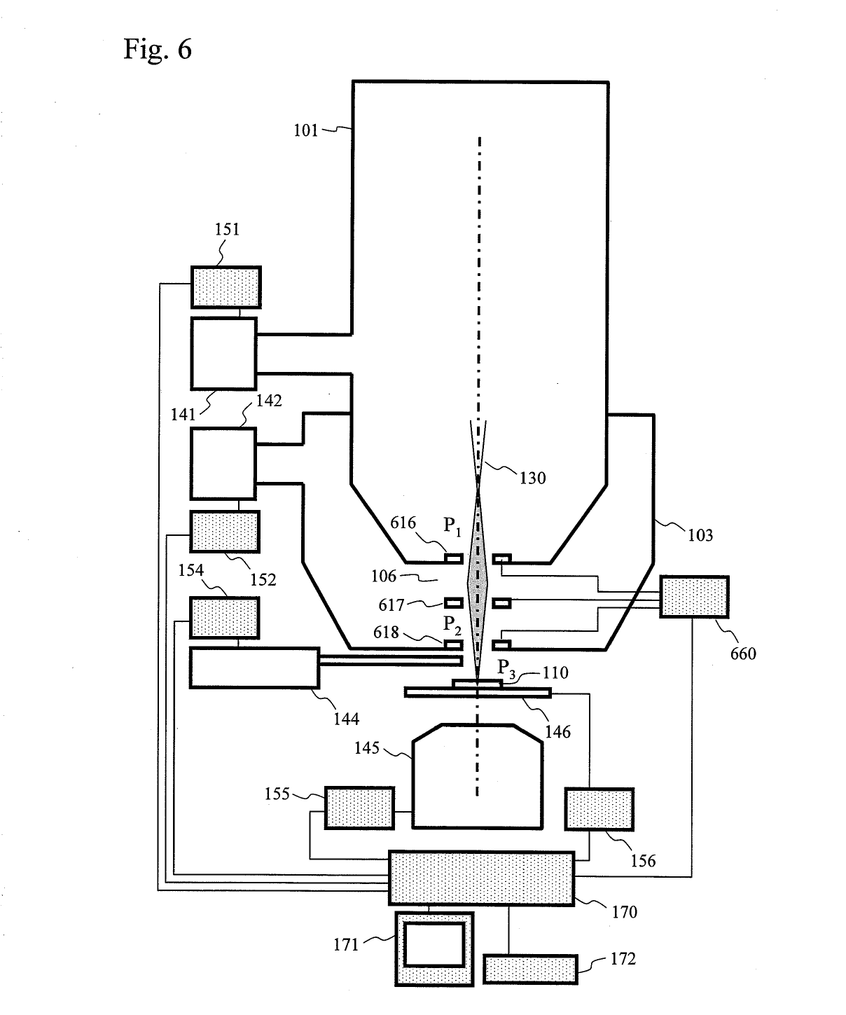

With reference to FIG. 6, a sixth example of the charged particle beam device according to the present invention will be described. The charged particle beam device according to the present example differs from the second example of FIG. 2 in that aperture electrodes 616, 617, and 618 are provided instead of the first and second differential evacuation diaphragms 108 and 109.

The aperture electrodes 616, 617, and 618 provide an objective lens function and a differential evacuation diaphragm function. Thus, in the present example, the charged particle beam optical system disposed in the charged particle beam column 101 is not provided with any objective lenses.

At the lower end of the charged particle beam column 101, the first aperture electrode 616 is disposed. At the lower end of the frontal sample chamber 103, the third aperture electrode 618 is disposed. Between the two aperture electrodes 616 and 618, the second aperture electrode 617 is disposed. The charged particle beam column 101 and the frontal sample chamber 103 are connected via the first aperture electrode 616. The frontal sample chamber 103 and the space in which the sample 110 is disposed are connected via the third aperture electrode 618. The aperture electrodes 616, 617, and 618 may include ring-shaped members with an internal diameter of not more than 2 mm.

The first aperture electrode 616 and the third aperture electrode 618 have a lens function and a differential evacuation diaphragm function. The second aperture electrode 617 has a lens function. Voltages of the aperture electrodes 616, 617, and 618 are controlled by an aperture electrode controller 660. By controlling the voltages of the aperture electrodes 616, 617, and 618, the lens operation is adjusted. Spaces 106 between the aperture electrodes 616, 617, and 618 constitute a lens chamber. In the present example, the frontal sample chamber 103 includes the lens chamber, so that the device configuration can be simplified compared with a case where the frontal sample chamber 103 and the lens chamber are provided separately.

In the present example, the third aperture electrode 618 that is the closest to the sample 110 is provided with the lens function and the differential evacuation diaphragm function. Thus, the distance between the lens and the sample 110 can be decreased, whereby the lens performance can be increased. Namely, the resolution of the charged particle beam image and processing precision can be increased. Further, in the present example, the distance between the differential evacuation diaphragm and the sample 110 can be decreased, whereby the distance that the charged particle beam travels under atmospheric pressure can be decreased. Namely, the scattering of the charged particle beam and energy loss can be avoided.

While in the present example the lens function is provided by three aperture electrodes, the number of the aperture electrodes is not particularly limited as long as the lens function can be provided. For example, the number of the aperture electrodes may be one, two, or four.

In the present example, the aperture electrodes 616 and 618 on both sides are provided with the differential evacuation diaphragm function. However, only one of the three aperture electrodes 616, 617, and 618 may be provided with the differential evacuation diaphragm function. Preferably, the aperture electrode 618 that is the closest to the sample 110 is provided with the differential evacuation diaphragm function. In this way, the distance that the charged particle beam travels under atmospheric pressure can be made sufficiently short. Namely, the scattering of the charged particle beam and energy loss can be avoided.

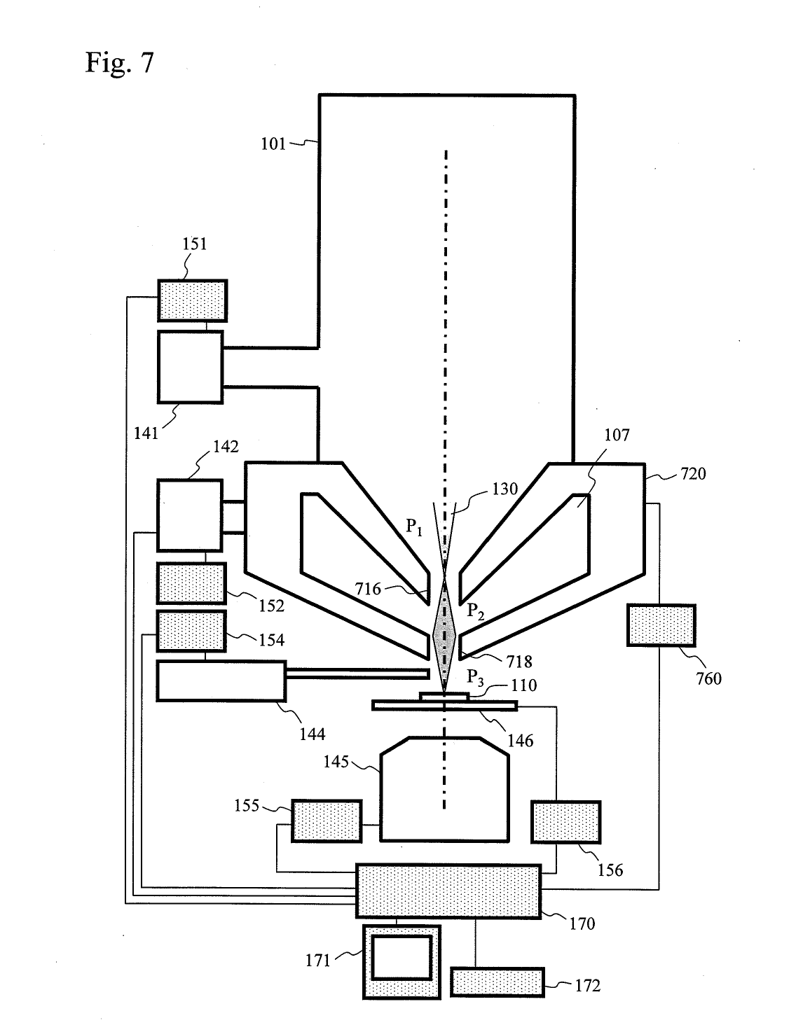

With reference to FIG. 7, a seventh example of the charged particle beam device according to the present invention will be described. The charged particle beam device according to the present example differs from the sixth example of FIG. 6 in that an electromagnetic lens 720 is used instead of the frontal sample chamber and the aperture electrode. The electromagnetic lens 720 is an objective lens constituting a charged particle beam optical system. The electromagnetic lens 720 is controlled by an electromagnetic lens controller 760.

The electromagnetic lens 720 according to the present example provides a frontal sample chamber function and a differential evacuation diaphragm function. First, the frontal sample chamber function will be described. The electromagnetic lens 720 has a magnetic path. The magnetic path forms a lens chamber 107 inside. The lens chamber 107 has an airtight container structure as in the frontal sample chamber 103, and is evacuated by the second vacuum pump 142.

Next, the differential evacuation diaphragm function will be described. The magnetic path of the electromagnetic lens 720 includes small openings 716 and 718 at the center. The openings 716 and 718 function as a differential evacuation diaphragm or a differential evacuation pipe.

In the present example, because the electromagnetic lens 720 is provided at the lower end of the charged particle beam column 101, the distance between the electromagnetic lens 720 and the sample 110 can be decreased. Thus, lens performance can be improved; namely, the resolution of the charged particle beam image and processing precision can be increased. Further, in the present example, the distance between the openings 716 and 718 of the magnetic path and the sample 110 can be decreased. As a result, the distance that the charged particle beam travels under atmospheric pressure can be decreased, whereby the scattering of the charged particle beam and energy loss can be avoided.

According to the present invention, a charged particle beam device that enables the processing of a sample supported under atmospheric pressure or low vacuum can be provided. For example, a device that enables fine processing of a biological sample or a moist substance by using FIB can be provided. Thus, the efficiency of manufacture of a thin-film sample for TEM or STEM observation can be significantly increased, and TEM or STEM analysis precision can be significantly improved.

Further, a sample supported under atmospheric pressure or under low vacuum can be irradiated with a charged particle beam with a small probe size. Thus, processing performance and observation performance of the charged particle beam device can be improved.

While the present invention has been described by way of examples, the present invention is not limited to any of the foregoing examples, and it will be appreciated by those skilled in the art that various modifications may be made within the scope of the invention defined in the following claims.

### DESCRIPTION OF REFERENCE NUMERALS

101, 102: charged particle beam column
102a: bent portion
102b: straight body portion
103: frontal sample chamber
104: sample chamber
106, 107: lens chamber
108: first differential evacuation diaphragm
109: second differential evacuation diaphragm
110: sample
130: charged particle beam
131: charged particle source
132: group of deflectors
133: deflector
135: shielding plate
141: first vacuum pump
142: second vacuum pump
143: third vacuum pump
144: helium gas introduction unit
145: optical microscope
146: sample stage
147: valve
148: detector
149: gas deposition unit
150: micro-sampling unit
151: first vacuum pump controller
152: second vacuum pump controller
153: third vacuum pump controller
154: helium gas introduction unit controller
155: optical microscope controller
156: sample stage controller
157: valve controller
158: detector controller
159: deflector group controller
160: deflector controller
161: gas deposition unit controller
162: micro-sampling unit controller
170: integrated computer
171: display
172: controller (keyboard, mouse, etc.)
416: opening
418, 518: differential evacuation pipe
616: first differential evacuation diaphragm/aperture electrode
617: aperture electrode
618: second differential evacuation diaphragm/aperture electrode
660: aperture electrode controller
716: opening (first differential evacuation diaphragm/magnetic path)
718: opening (second differential evacuation diaphragm/magnetic path)
720: electromagnetic lens
760: electromagnetic lens controller

1. An ion beam device comprising:
a sample stage supporting a sample;
an ion beam optical system that focuses an ion beam from an ion source on the sample;
an ion beam column housing the ion beam optical system;
a first differential evacuation diaphragm attached to the ion beam column;
a frontal sample chamber disposed in connection with the ion beam column via the first differential evacuation diaphragm;
a second differential evacuation diaphragm attached to the frontal sample chamber;
a first vacuum pump for evacuating the ion beam column; and
a second vacuum pump for evacuating the frontal sample chamber,
wherein:
the ion beam from the ion source is configured to irradiate the sample via the ion beam optical system, the first differential evacuation diaphragm, and the second differential evacuation diaphragm;
the first vacuum pump and the second vacuum pump are controlled such that P1<P2<P3, where P1 is an air pressure of the ion beam column, P2 is an air pressure of the frontal sample chamber, and P3 is an air pressure of a space around the sample; and
the first and second differential evacuation diaphragms have an internal diameter of not more than 2 mm.

2. The ion beam device according to claim 1, wherein the ion beam optical system includes
a shielding plate disposed in such a manner as to intersect an optical axis of the ion source, and
a group of deflectors for bending a path of the ion beam from the ion source in such a manner as to bypass the shielding plate.

3. The ion beam device according to claim 1, comprising a helium gas introduction unit for introducing helium gas in a path of the ion beam between the second differential evacuation diaphragm and the sample.

4. The ion beam device according to claim 1, comprising an optical microscope for observing an irradiating position of the ion source on the sample.

5. The ion beam device according to claim 1, comprising:
a sample chamber housing the sample stage;
a third vacuum pump for evacuating the sample chamber; and
a valve configured to be opened or closed for connecting the sample chamber with the atmosphere.

6. The ion beam device according to claim 1, wherein:
the ion beam column includes a straight body portion and a bent portion bent with respect to the straight body portion;
the ion source is attached to the bent portion; and
the ion beam optical system includes a deflector for deflecting the ion beam from the ion source.

7. The ion beam device according to claim 1, comprising a gas deposition unit and a micro-sampling unit that are disposed around the sample.

8-9. (canceled)

10. An ion beam device comprising:
a sample stage supporting a sample;
an ion beam optical system that focuses an ion beam from an ion source on the sample;
an ion beam column housing the ion beam optical system;
a differential evacuation pipe connecting the ion beam column and a space around the sample; and
a vacuum pump for evacuating the ion beam column,
wherein:
the ion beam from the ion source is configured to irradiate the sample via the ion beam optical system and the differential evacuation pipe;
the vacuum pump is controlled such that P1<P3, where P1 is an air pressure of the ion beam column, and P3 is an air pressure of the space around the sample;
a distance between the differential evacuation pipe and the sample is not more than 2 mm; and
the differential evacuation pipe has an internal diameter of not more than 3 mm.

11. The ion beam device according to claim 10, wherein:
the ion beam optical system includes a shielding plate disposed in such a manner as to intersect the optical axis of the ion source, and a group of deflectors for bending a path of the ion beam from the ion source in such a manner as to bypass the shielding plate.

12. The ion beam device according to claim 10, comprising a helium gas introduction unit for introducing helium gas in a path of the ion beam between the differential evacuation pipe and the sample.

13. The ion beam device according to claim 10, comprising an optical microscope for observing an irradiating position of the ion source on the sample.

14. The ion beam device according to claim 10, comprising a gas deposition unit and a micro-sampling unit that are disposed around the sample.

15-20. (canceled)

21. The ion beam apparatus according to claim 1, wherein the second differential evacuation diaphragm has the shape of a tube.

22. The ion beam apparatus according to claim 21, wherein the tube is configured to limit the flow volume of a gas per unit time.

23. The ion beam apparatus according to claim 1, wherein the second differential evacuation diaphragm has an aperture electrode function of focusing the ion beam.

24. The ion beam apparatus according to claim 1, wherein the second differential evacuation diaphragm has a magnetic pole function of focusing the ion beam.
